(19) United States
(12) Patent Application Publication
(10) Pub. No.: US 2026/0195510 A1
(43) Pub. Date: Jul. 9, 2026

(54) DYNAMIC UPDATES OF RESERVOIR PROPERTIES OF A NUMERICAL RESERVOIR SIMULATION MODEL

(71) Applicant: Saudi Arabian Oil Company, Dhahran (SA)

(72) Inventors: Ali A. Al-Turki, Khobar (SA); Majdi A. Baddourah, Dhahran (SA); Osaid F. Hajjar, Dammam (SA)

(21) Appl. No.: 19/009,214

(22) Filed: Jan. 3, 2025

(51) Int. Cl. G06F 30/28

(52) U.S. Cl. CPC G06F 30/28

(57) ABSTRACT

The present disclosure relates to computer-implemented methods, software, and systems for dynamic updating of reservoir properties of a numerical reservoir simulation model. Input data associated with changes of properties of a geological model of a reservoir due to fracking events can be obtained. A simulation event file can be generated to include instructions to provide portions of the input data to guide an execution of a numerical simulation model. The simulation event file can be provided as input during the execution of the numerical simulation model to calibrate, based on the instructions of the simulation event file, the numerical simulation model with the geological model of the reservoir. A calibrated numerical simulation model can be generated based on processing the input data associated with the changes of the properties of the geological model of the reservoir during the execution of the numerical simulation model.

### TECHNICAL FIELD

The present disclosure relates to computer-implemented methods, software, and systems for data processing.

### BACKGROUND

A reservoir simulation model can simulate past or future behavior of a reservoir. Simulation engineers typically compare the simulation results with field data. During this process, an engineer can review the quality of the field data and decide how to use it in the simulation.

### SUMMARY

The present disclosure involves systems, software, and computer implemented methods for dynamic updating of reservoir properties of a numerical reservoir simulation model.

One example method may include operations such as: obtaining input data associated with changes of properties of a geological model of a reservoir due to fracking events; generating a simulation event file, wherein the simulation event file includes instructions to provide portions of the input data to guide an execution of a numerical simulation model, and wherein the instructions are generated for each of the fracking events; providing the simulation event file as input during the execution of the numerical simulation model to calibrate, based on the instructions of the simulation event file, the numerical simulation model with the geological model of the reservoir; and generating a calibrated numerical simulation model based on processing the input data associated with the changes of the properties of the geological model of the reservoir during the execution of the numerical simulation model.

In some instances, the method can include providing the calibrated numerical simulation model for use in reservoir development.

In some instances, generating the simulation event file can include: chronologically sorting the fracking events based on time stamps associated with each event of the fracking events, wherein the instructions correspond to the fracking events, wherein the instructions include the input data for each of the fracking events generated based on the input data, and wherein the instructions are ordered in the simulation event file according to the chronologically sorted fracking events.

In some instances, the input data can be data for a set of the properties of the geological model, the set of the properties including permeability and porosity. In some instances, the input data is historical data associated with observed fracking events for the reservoir. In some instances, the input data is prediction data including prediction values for properties associated with the properties of the reservoir. The prediction values can be associated with predicted future fracking events.

In some instances, each instruction from the instructions part of the simulation event file includes data for one or more of: reservoir properties, fracture properties, and well constraints, and wherein the geological model of the reservoir includes static reservoir properties and dynamic reservoir properties.

In some instances, during the execution of the numerical simulation model, portions of data from the simulation event file are provided, where each portion corresponds to a fracking event. During the processing of a first portion of the input data that is provided for use during a simulation, a timestep size can be applied for processing data during the simulation. The timestep size can be determined according to a size rule for updating of the properties of the reservoir at the numerical simulation model. In some instances, the size rule can define at least one threshold value to be used as the timestep size for each processing of a portion of the input data during the simulation to maintain smooth convergence.

Similar operations and processes may be performed in a system including at least one processor and a memory communicatively coupled to the at least one processor, where the memory stores instructions that when executed cause the at least one processor to perform the operations. Further, a non-transitory computer-readable medium storing instructions which, when executed, cause at least one processor to perform the operations is also contemplated. In other words, while generally described as computer implemented software embodied on tangible, non-transitory media that processes and transforms the respective data, some or all of the aspects may be computer implemented methods or included in respective systems or other devices for performing this described functionality.

It is appreciated that methods, in accordance with the present disclosure, can include any combination of the aspects and features described herein. That is, methods in accordance with the present disclosure are not limited to the combinations of aspects and features specifically described herein, but also include any combination of the aspects and features provided.

The details of these and other aspects and embodiments of the present disclosure are set forth in the accompanying drawings and the description below. Other features, objects, and advantages of the disclosure will be apparent from the description, the drawings, and the claims.

### DESCRIPTION OF DRAWINGS

FIG. 1 is a block diagram depicting an example computer-based architecture, in accordance with implementations of the present disclosure.

FIG. 2 is a block diagram of an example method for calibrating a numerical simulation model with a geological model of a reservoir undergoing changes due to fracking events, in accordance with implementations of the present disclosure.

FIG. 3A is a block diagram of an example method for calibrating a numerical simulation model based on input for changes in properties of a geological model of a reservoir due to fracking events, in accordance with implementations of the present disclosure.

FIG. 3B is a block diagram of an example of a simulation event file to be used to guide execution of a numerical simulation model for a reservoir in the field, in accordance with implementations of the present disclosure.

FIG. 4 is a flowchart of an example of process for processing portions of the data in a simulation event file during numerical simulation execution for a reservoir, in accordance with implementations of the present disclosure.

FIG. 5 is a block diagram illustrating an example of a computer-implemented system used to provide computational functionalities associated with described algorithms, methods, functions, processes, flows, and procedures, in accordance with implementations of the present disclosure.

FIG. 6 illustrates hydrocarbon production operations that include both one or more field operations and one or more computational operations, which exchange information and control exploration for the production of hydrocarbons.

### DETAILED DESCRIPTION

The present disclosure describes various tools and techniques for dynamic updating of reservoir properties of a numerical reservoir simulation model and is presented to enable any person skilled in the art to make and use the disclosed subject matter in the context of one or more particular implementations. Various modifications, alterations, and permutations of the disclosed implementations can be made and will be readily apparent to those of ordinary skill in the art, and the general principles defined can be applied to other implementations and applications, without departing from the scope of the present disclosure. In some instances, one or more technical details that are unnecessary to obtain an understanding of the described subject matter and that are within the skill of one of ordinary skill in the art may be omitted so as to not obscure one or more described implementations. The present disclosure is not intended to be limited to the described or illustrated implementations, but to be accorded the widest scope consistent with the described principles and features.

A reservoir model can represent a physical space of a reservoir (e.g., an oil, water, or gas reservoir) that can be a two-dimensional (2D) or three-dimensional (3D) model defined as an array of cells over a grid. In some instances, the cells of the model can be associated with values of attributes such as porosity, permeability, and/or water saturation. The value of such attributes can apply (e.g., uniformly or particularly defined) throughout a volume of the reservoir represented by a cell.

In some instances, reservoir modeling can involve the construction of a computer model of a reservoir (e.g., a petroleum reservoir) to be used to estimate production and to support the development of the reservoir. Future production of the reservoir can be predicted and used in the planning of including more wells to be placed and/or modifications or alternations of the reservoir management.

In general, a reservoir simulation model can be created to simulate the flow of fluids within a reservoir over the reservoir's production lifetime. Using the simulation, the flow of fluids through porous media can be predicted. The reservoir model can be associated with static or dynamic variables that, during simulation, can be updated to match real-time production data.

During the lifespan of a field, a reservoir can undergo induced geology changes that can span from around the wells (e.g., producers and/or injectors) to locations away from the wells. In some cases, these changes may introduce favorable changes to features of the reservoir, such as better reservoir connectivity, conductivity, and production/injection, among other examples. In some cases, changes to features of the geology of a reservoir can be a result of induced hydraulic fractures or attributed to production/injection operations. For example, fractures can introduce changes to the reservoir's permeability and porosity as originally observed. Induced changes to a reservoir from hydraulic fractures can have a great impact on the productivity and injectivity of the wells for the reservoir.

In some cases, to reflect those changes on the respective reservoir simulation model, a well productivity index (PI) can be adjusted to reflect the impact of the hydraulic fracturing job. However, there are some downsides to such practice since if the well PI is adjusted without adjusting the geological model of the reservoir, the geological model of the reservoir will not be reflective anymore. In such a way, the relationship between the reservoir simulation model and the geological model of the reservoir can be lost and if changes are applied to one of the models the other one would not be reflected, and as a result the two models, the reservoir geology model and the simulation model, will not be inconsistent over time.

In some instances, a process to update a geological model of the reservoir based on historical or futuristic fracking events, and to reflect induced changes by fracking processes to a numerical simulation mode of the reservoir can be performed. In some instances, the updates can be performed by interacting with the numerical simulation model and provide guiding instructions according to a generated event simulation file to determine changes to static properties of the reservoir (e.g., permeability and porosity) and to reflect those changes on the geological model of the reservoir. In some instances, information about fracking events can be provided as input to the numerical simulation execution through the generation of an event file that can be used during the execution of the numerical reservoir simulation model.

Conventionally, reservoir simulation studies rely on building and updating a reservoir simulation model. The reservoir model can incorporate static (geological) reservoir properties (e.g., permeability, porosity, facies, initial volumetric, saturations, and contacts) and dynamic properties (e.g., end-point relative permeability, production, and injection).

A conventional workflow for building and running a numerical simulation model for the reservoir may not account for the geo-mechanical changes or modifications to the properties of the reservoir induced by fracking processes. In accordance with implementations of the present disclosure, a process to update the numerical simulation model can be implemented to account for the reservoir's geology changes due to fracking. In some instances, the process can include providing data for hydraulic fracturing events for generating a simulation event file, that is to be used as input when executing the numerical simulation model as part of a simulation study for the reservoir. In some cases, the input data can be data associated with historical fracking events to study the changes occurring at the reservoir and to use the learned patterns for prediction scenarios. In some other cases, the input data can be associated with predicted data for future fracking events that are to be induced for the reservoir, and through inputting the data into the simulation, a prediction of the changes for the reservoir can be determined.

The output of such processes can be used in the context of reservoir management and field planning. In some instances, the event file can include both historical fracking events that occurred in the past, as well as futuristic fracking events (e.g., planned events, events considered for evaluation and determination of the fracking events to be induced in the future, and over time). In some instances, the simulation execution can be governed by tags and/or keywords included in the simulation event file that are read during simulation runtime to provide additional data to the simulation associate with properties of the reservoir model that are related to changes due to fracking events.

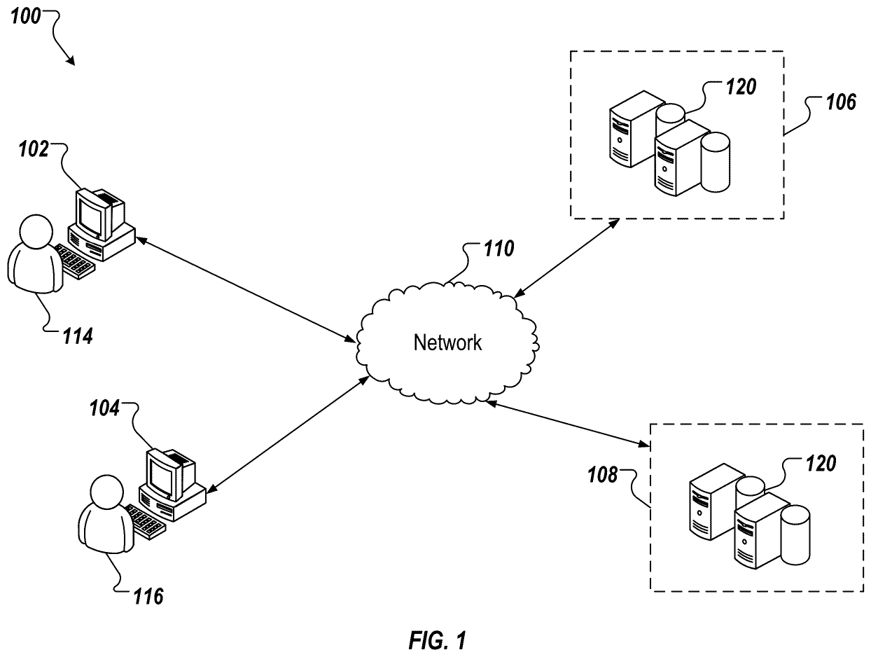

FIG. 1 is a block diagram depicting an example computer-based architecture 100, in accordance with implementations of the present disclosure. In the depicted example, the example architecture 100 includes a client device 102, a client device 104, an environment 106, an environment 108, and a network 110. The environment 106 and the environment 108 may be a cloud environment. The environment 106 and the environment 108 may include corresponding one or more server devices and databases (e.g., processors, memory). In the depicted example, a user 114 interacts with the client device 102, and a user 116 interacts with the client device 104.

In some examples, the client device 102 and/or the client device 104 can communicate with the environment 106 and/or the environment 108 over the network 110. The client device 102 can include any appropriate type of computing device such as a desktop computer, a laptop computer, a handheld computer, a tablet computer, a personal digital assistant (PDA), a cellular telephone, a network appliance, a camera, a smartphone, an enhanced general packet radio service (EGPRS) mobile phone, a media player, a navigation device, an email device, a game console, or an appropriate combination of any two or more of these devices, or other data processing devices. In some implementations, the network 110 can include a large computer network, such as a local area network (LAN), a wide area network (WAN), the Internet, a cellular network, a telephone network (e.g., PSTN), or an appropriate combination, thereof connecting any number of communication devices, mobile computing devices, fixed computing devices and server systems.

In some implementations, the environment 106 includes at least one server and at least one data store 120. In the example of FIG. 1, the environment 106 is intended to represent various forms of servers including, but not limited to a web server, an application server, a proxy server, a network server, and/or a server pool. In general, server systems accept requests for application services and provides such services to any number of client devices (e.g., the client device 102 over the network 110) and other service requests, as appropriate.

In some instances, the environments 106 and 108 may host one or more client applications, application servers, and authorization servers to support the execution of secure requests between the client applications and the application server. In some instances, the users 114 and/or 116 may access a client application through the network 110.

In some instances, the client devices 102 and/or 104 can host logic for generating a simulation event file and providing it as input to a simulation model to account for changes to the geological model of the reservoir due to hydraulic fractures. The numerical simulation model can be calibrated to more accurately predict reservoir measurable quantities.

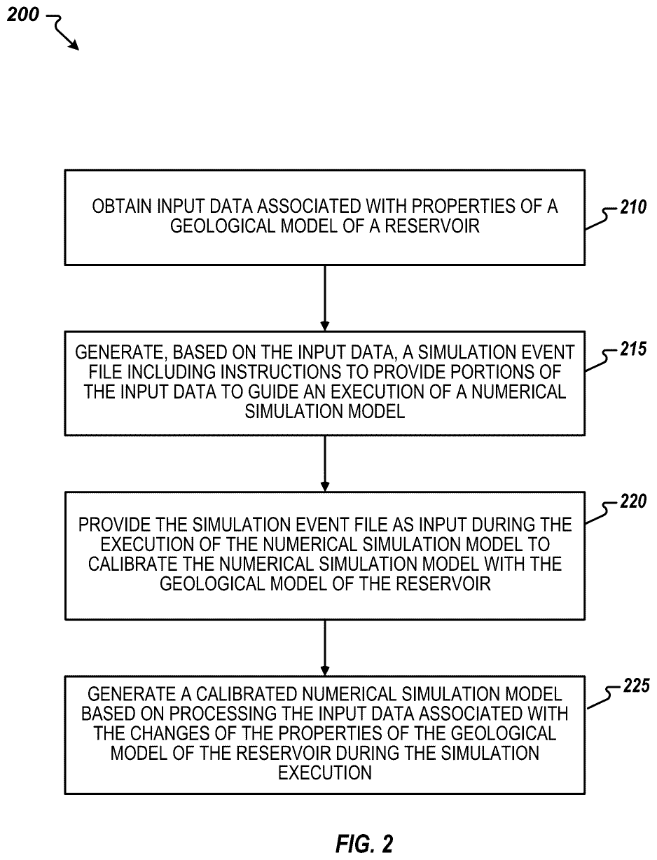

FIG. 2 is a block diagram of an example method 200 for calibrating a numerical simulation model with a geological model of a reservoir undergoing changes due to fracking events, in accordance with implementations of the present disclosure. The method 200 can be executed at a computing environment, for example, such as the environment 106 and/or 108. The method 200 can be executed to account for geo-mechanical changes to a geological model of a reservoir when simulating fluid flows. Based on the operations of the method 200, changes to the reservoir properties and well behavior due to fracking events can be accounted for during numerical reservoir simulations.

At 210, input data associated with the changes of the properties of a geological model of a reservoir is obtained. The input data is associated with fracking events related to the reservoir. In some instances, the input data can be associated with historically observed fracking events for the reservoir. In some instances, the input data can be associated with predicted future fracking events for the reservoir. The input data can be used to dynamically update the numerical simulation model. In some instances, the fracking events can be predefined future events to be performed for the reservoir, where the data for such fracking events can be used for sensitivity analysis to study the fracture designs and respective reservoir/well response to such changes.

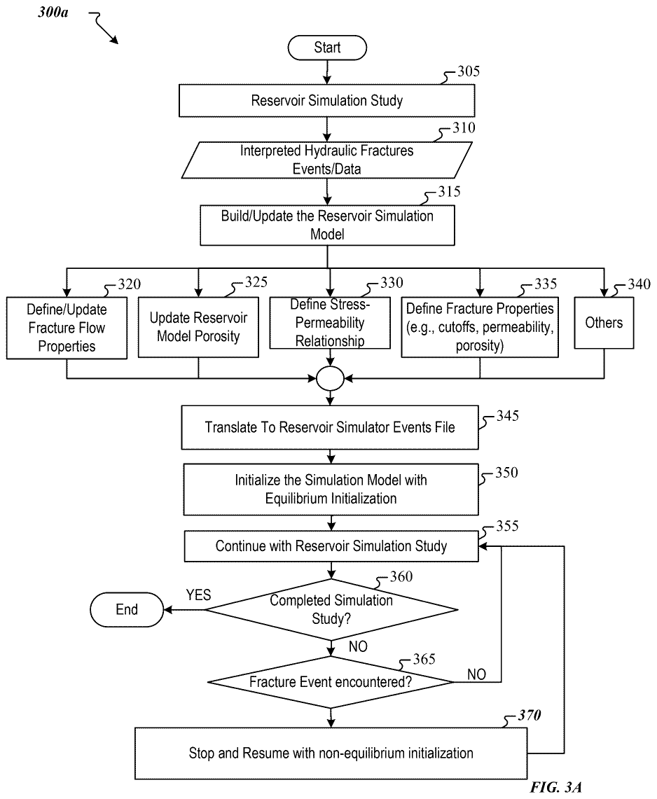

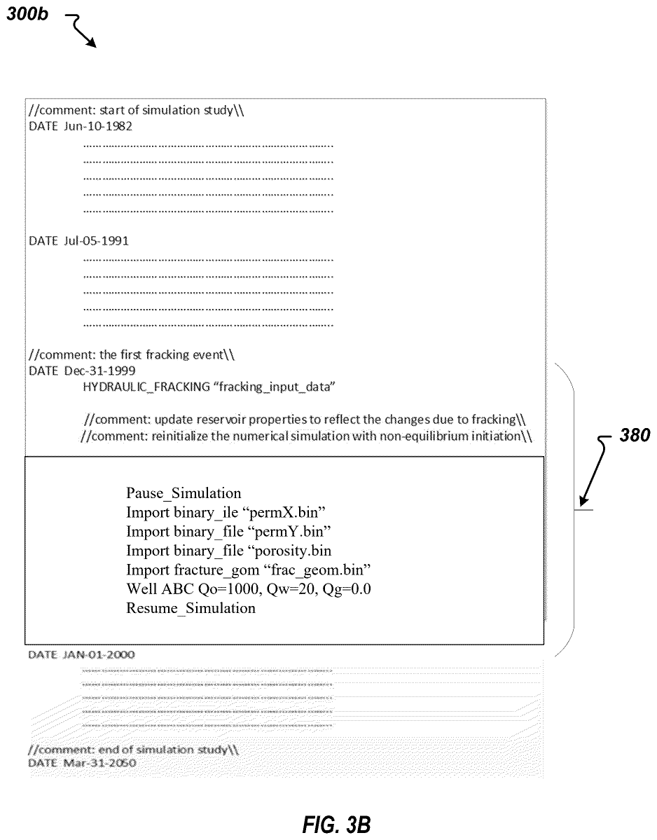

At 215, a simulation event file can be generated based on the input data. The simulation event file can include instructions that are usable to guide an execution of a numerical simulation model based on data for the fracking events. The simulation event file can include instructions to provide portions of the input data to guide an execution of the numerical simulation model. The guidance of the execution can be with regard to supporting how to handle prediction requirements related to occurrences of fracking events, that result in changes in the reservoir model and the well requirements. In some instances, the simulation event file can be organized to store instructions for fracking events ordered in a chronological order based on their time stamp. For example, the simulation event file can be the example simulation event file 300b of FIG. 3B.

In some instances, the simulation event file can be generated by chronologically ordering the fracking events based on their time stamp. In some instances, for each fracking event, respective instructions can be generated. The instructions can include data for each of the fracking events generated based on the input data. In some instances, the instructions can include reference to data files including information about reservoir properties, fracture properties, well constraints, or others. The generated instructions can be combined in a single file in the order of the time stamps associated with each fracking event, so that the simulation event file can be generated. The simulation event file can be provided as input, as described at 220.

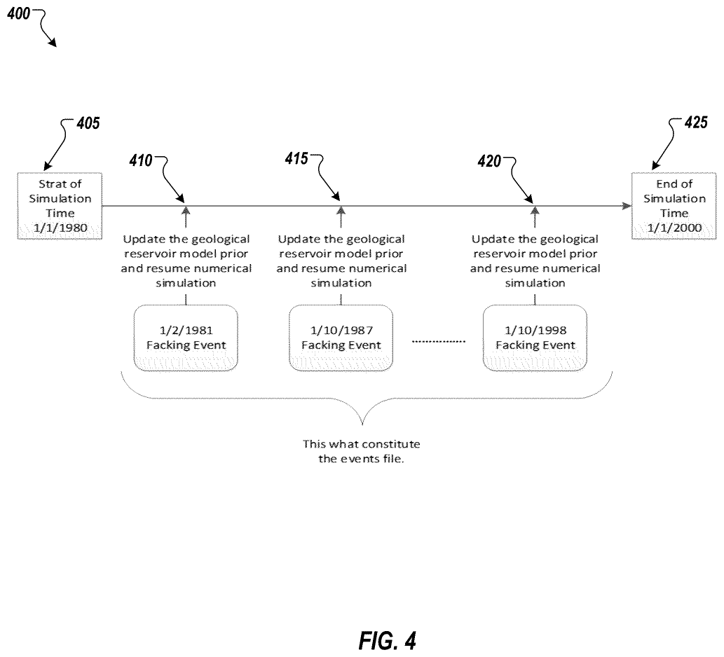

At 220, the simulation event file can be provided as input during the execution of the numerical simulation model to calibrate, based on the instructions of the simulation event file, and the numerical simulation model with the geological model of the reservoir. The simulation event file can include instructions ordered according to chronologically sorted fracking events identified with the obtained input data. The simulation event file can be input into the execution in portions, for each of the fracking events as associated with a respective time of occurrence. For example, the simulation event file can be processed as described in relation to FIG. 4.

In some instances, as described in relation to FIGS. 3A, 3B, and 4, during the execution of the numerical simulation model, portions of data from the simulation event file can be processed. Each portion can correspond to a flacking event identified in the simulation event file. During the processing of the first portion of the data that is provided for use during the simulation, a timestep size can be applied for processing the data during the simulation. The timestep size can be determined according to a size rule for updating of the properties of the reservoir in the numerical simulation model. In some instances, the size rule can be defined to include at least one threshold value to be used as the timestep size for each processing of a portion of the data during the simulation to maintain smooth convergence.

By updating the reservoir properties to reflect fracking events, and reducing the timestep size, small changes to pressure and saturations is ensured. It is a common practice for smooth convergence to a solution of the flow equations. The timestep size will increase as the numerical solution progresses. It might slow down the numerical simulation each time it resumes after encountering a fracking event; however, this small cost will ensure the stability and accuracy of the numerical solution.

At 225, a calibrated numerical simulation model can be generated based on processing the input data associated with the changes of the properties of the geological model of the reservoir. In some instances, the calibrated numerical simulation model can be provided for use in reservoir development.

In some instances, when the method 200 is used to study the fracture design and reservoir or well responses due to changes in the reservoir model, the calibrated simulation model can be used for effective field development planning, field management, and forecasting characteristics of the reservoir over time.

FIG. 3A is a block diagram of an example method 300a for calibrating a numerical simulation model based on input for changes in properties of a geological model of a reservoir due to fracking event, in accordance with implementations of the present disclosure. The method 300a calibrates a numerical simulation model for a reservoir with a geological model of the reservoir to provide consistency between a reservoir model and a simulation model in cases where hydraulic fracking is induced and the reservoir model is changed.

In some instances, simulation results can be obtained from executing the calibrated simulation model and can be used to predict field data. For example, the simulation can simulate a petroleum reservoir to determine productive rates. However, simulation results may differ from observed data, and thus the simulation model may need to be adjusted. Observed field data from a reservoir for a respective period of time can be obtained and used to adjust the simulation model. In some instances, the simulation execution can be associated with the simulation of the formation of porosity and/or permeability properties of the reservoir due to changes based on hydraulic fracking.

The method 300a includes triggering a reservoir simulation study at 305, where interpreted hydraulic fracture data for a fracking event(s) is received at 310. The hydraulic fracture data can include portions of data associated with respective different fracture events that can be annotated with a time stamp. As previously described, the data can be historical data or can be futuristic planning data that can be generated for exploratory analysis for the reservoir. In some instances, the received data at 310 can be substantially similar to the obtained input data at 210 of FIG. 2.

At 315, a reservoir simulation model can be built (or updated), where the model can be defined by defining different properties of port hydraulic fracturing. For example, the different properties can include one or more of:
Defining fracture flow properties (at 320),
Defining reservoir model porosity (at 325),
Defining stress-permeability relationship (at 330),
Defining fracture properties (e.g., cutoffs, permeability, and porosity) (at 335), or
Other properties (e.g., production, injection, flowing pressure) (at 340).

In some instances, the data associated with these properties is of various data types and can be used to model and characterize changes to a geological model of a reservoir. The data for each fracking event as in the received hydraulic fractures data at 310 can be “translated” into a simulation event file that can be provided for consumption of a non-geomechanics simulation model for the reservoir. For example, the simulation event can be as the simulation event file 300b shown at FIG. 3B.

In some instances, the data for the hydraulic fracture events can be used to generate the simulation event file (at 345) and to include data for properties such as the properties of the built simulation model at 315, i.e., such as fracture properties, reservoir model porosity, stress-permeable relationship, fracture flow properties, well constraints, among other examples. At 350, the execution of the simulation model can be started where the simulation model can be initialized with an equilibrium initialization. In some instances, the equilibrium initialization can be defined to use depth and fluid densities for each grid-cell in the geological model to calculate pressure and saturation. In some instances, the state of the reservoir can be represented by defining reservoir pressure, saturation, and factors associated with the volume formation.

At 355, after the initialization, the simulation execution can be continued, where the timestep used for the numerical simulation can be reduced to a timestep size that is defined based on a step size rule to minimize or avoid numerical convergence issues and unnecessary timestep cuts. For example, the timestep size can be set to a threshold value initially, and can be changed over time during the simulation, or can be kept as a fixed value.

The simulation execution can be performed by processing data from the simulation event file, and when encountering a hydraulic fracturing event (at 365), the simulation can be paused or stopped, at 370, and a new initialization of the simulation model can be provided to calibrate the model to the changes in the properties due to the fracking event. In some cases, if a non-equilibrium initialization is used, the numerical reservoir simulation can resume its execution based on reservoir states that are the states that were calculated at the time when the simulation was paused or stopped (as at 370).

The data to be used for the new initialization can be obtained based on processing the data for the respective fracking event from the simulation event file. If the simulation execution is determined to be completed, at 360, the process can be finalized, and the calibrated simulation model can be provided. If the simulation execution is determined as not yet completed, at 360, the simulation can continue until another fracturing event can be encountered (at the check 365). Based on the execution of the method 300a, a calibrated simulation model can be provided that is modified or updated based on the understanding of the changes that are incurred in a geological model of a reservoir, as provided through the simulation event file in iterations.

FIG. 3B is a block diagram of an example 300b of a simulation event file to be used to guide the execution of a numerical simulation model for a reservoir in the field, in accordance with implementations of the present disclosure. In some instances, the simulation event file can be a file that can be used in the method 200 of FIG. 2 or can be a file that is generated as described in relation to FIG. 3A (e.g., the translation of the event file at 345).

In some instances, the simulation event file can include a section with instructions related to different fracking events, where the fracking events can be identified with a particular time stamp (e.g., “DATE DEC 31-1999”). The time stamp can be provided in various formats. The sections in the simulation event file can correspond to the fracking events identified in input data for the reservoir model that undergoes hydraulic fractures. The sections can be ordered in a chronological manner based on sorting the fracking events based on their time stamp from the earliest to the latest fracking event. As the numerical simulation progresses, the fracking events are encountered, as explained in relation to FIG. 3A, at 365, and the data for the reservoir geology is provided for consideration during the simulation. After a section of the simulation event file is obtained during the execution of the numerical simulation execution, the numerical simulation can resume its execution but with an update for the parameters of the simulation model. As such the numeric simulation model is calibrated in iterations based on the data obtained through the simulation event file.

In some instances, a section 380 of the simulation event file can be associated with a first fracking event, where the section 380 includes instructions on how to obtain data related to the fracking event during the execution of the simulation model. The instructions can include instructions for importing data from a reference resource, to obtain parameter values for properties of the reservoir model, the well, or other.

In some instances, the events in the simulation event file can be listed as they occur in time in the form of a series of keywords and respective input data. For example, a single fracking event can have a simulator of keywords and respective data that can include values for properties of the reservoir affected by the respective fracking event. The data that can be included for a given fracking event can include one or more of:
Matrix properties (e.g., permeabilities and porosity),
Fracture properties (e.g., permeabilities, porosity, geometry, and half-length), and/or
well constraints (e.g., new flow rates, bottomhole pressure, and wellhead pressure).

The numerical simulation model can recognize, during its execution and processing of the simulation event file, the keywords part of the simulation event file to instruct the simulation execution to perform actions and to process input data as provided through the simulation event file (e.g., based on reference to file locations or storage paces). The simulation event file can include instructions to import relevant data for properties of the reservoir that are to be imported in the simulation model to calibrate its execution based on performing updates. The updating of the simulation model can be performed as described in relation to FIGS. 2, 3A, and 3B.

FIG. 4 is a flowchart of an example of a process 400 for processing portions of the data in a simulation event file during numerical simulation execution for a reservoir, in accordance with implementations of the present disclosure. In some instances, the simulation event file can be substantially similar to the generated simulation event file at 215 of FIG. 2, or as the translated simulation event file at 350 of FIG. 3A, or as the example simulation event file 300b of FIG. 3B. In some instances, a simulation event file can be generated to include instructions referencing data to be used during the execution of a numerical simulation model. The simulation event file can be provided for consumption during the execution of the numerical simulation model so that, when the simulation is started at 405, the simulation is executed in relation to a given time period, past or future period. The simulation event file can include data for fracking events that are past or future events and that are aligned with the simulation study of the reservoir. As shown in FIG. 4, the simulation can be started to simulate fluid behavior in a reservoir for a period between Jan. 1, 1980 and Jan. 1, 2000. In some instances, the simulation event file can include time stamps for each fracking event that are provided in a particular, predefined, time format. In some instances, the obtained information for the fracking events can include time stamps that are in the same or different format, and when the simulation event file is generated, the format of the time stamps can be converted to the predefined time format for the simulation event file.

During the simulation, a first fracking event can be identified, that is associated with a first in order time stamp, i.e., at Jan. 2, 1981, from the simulation event file. The format for storing the time stamp in the simulation event file is not limited to the format of “month/day/year” as shown, and can take other format as defined for the simulation event file, or configured otherwise. The data references for this first fracking event in the simulation event file can be used to modify or update properties of the reservoir (e.g., such as properties used to build the simulation model as references at 320, 325, 330, 335, and 340 of FIG. 3A) as used by the numerical simulation model and to proceed with the simulation based on the modified properties. The determination to modify or update properties of the reservoir can be based on processing the instructions provided in the respective section/portion of the simulation event file, e.g., as shown at section 380 of FIG. 3B.

The simulation execution can be interrupted at time points 415 and 420, where input for another fracking event that is encountered at the simulation event file can be obtained and processed to update the properties of the numerical simulation model and to proceed with the simulation. The simulation can be completed, and the provided simulation model can be calibrated based on the obtained data from the simulation event file.

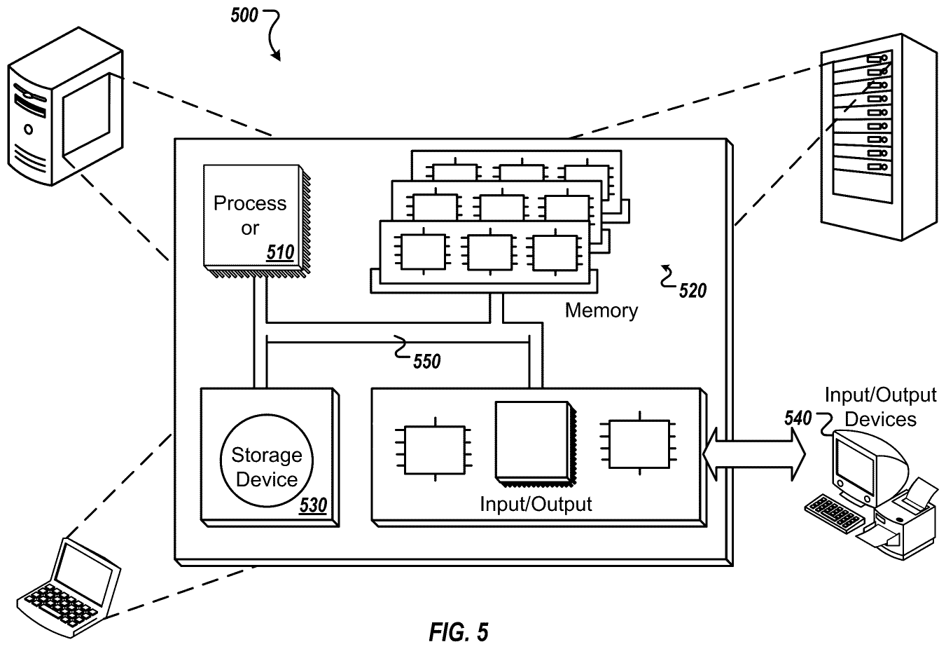

Referring now to FIG. 5, FIG. 5 is a block diagram illustrating an example of a computer-implemented system 500 used to provide computational functionalities associated with described algorithms, methods, functions, processes, flows, and procedures, in accordance with implementations of the present disclosure. The system 500 can be used for the operations described in association with the implementations described herein. For example, the system 500 may be included in any or all of the server components discussed herein. The system 500 includes a processor 510, a memory 520, a storage device 530, and an input/output device 540. The components 510, 520, 530, and 540 are interconnected using a system bus 550. The processor 510 is capable of processing instructions for execution within the system 500. In some implementations, the processor 510 is a single-threaded processor. In some implementations, the processor 510 is a multi-threaded processor. The processor 510 is capable of processing instructions stored in the memory 520 or on the storage device 530 to display graphical information for a user interface on the input/output device 540.

The memory 520 stores information within the system 500. In some implementations, the memory 520 is a computer-readable medium. In some implementations, the memory 520 is a volatile memory unit. In some implementations, the memory 520 is a non-volatile memory unit. The storage device 530 is capable of providing mass storage for the system 500. In some implementations, the storage device 530 is a computer-readable medium. In some implementations, the storage device 530 may be a floppy disk device, a hard disk device, an optical disk device, or a tape device. The input/output device 540 provides input/output operations for the system 500. In some implementations, the input/output device 540 includes a keyboard and/or pointing device. In some implementations, the input/output device 540 includes a display unit for displaying graphical user interfaces.

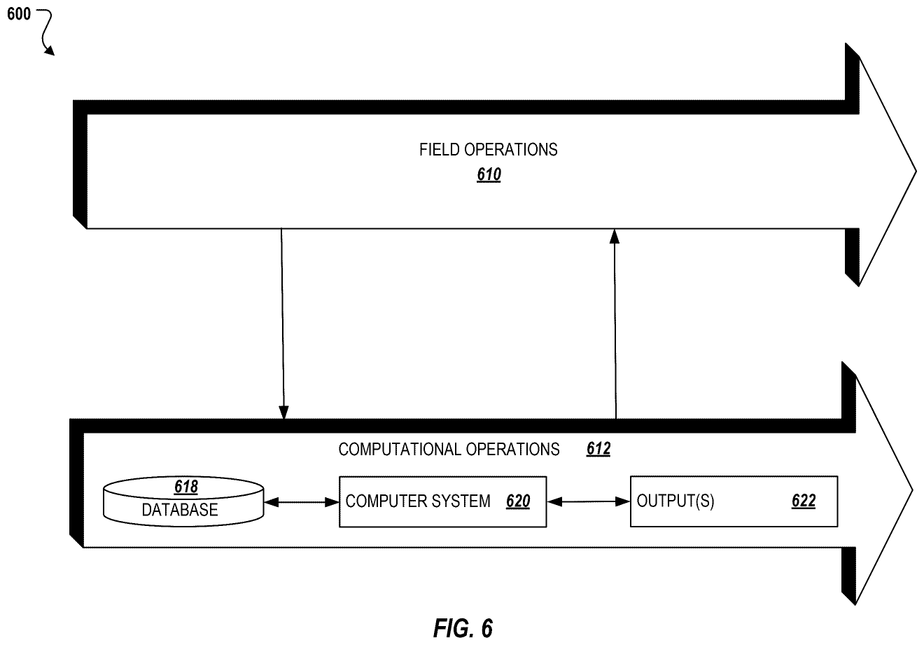

FIG. 6 illustrates hydrocarbon production operations 600 that include both one or more field operations 610 and one or more computational operations 612, which exchange information and control exploration for the production of hydrocarbons. In some implementations, outputs of techniques of the present disclosure can be performed before, during, or in combination with the hydrocarbon production operations 600, specifically, for example, either as field operations 610 or computational operations 612, or both.

Examples of field operations 610 include forming/drilling a wellbore, hydraulic fracturing, producing through the wellbore, injecting fluids (such as water) through the wellbore, to name a few. In some implementations, methods of the present disclosure can trigger or control the field operations 610. For example, the methods of the present disclosure can generate data from hardware/software including sensors and physical data gathering equipment (e.g., seismic sensors, well logging tools, flow meters, and temperature and pressure sensors). The methods of the present disclosure can include transmitting the data from the hardware/software to the field operations 610 and responsively triggering the field operations 610 including, for example, generating plans and signals that provide feedback to and control physical components of the field operations 610. Alternatively, or in addition to, the field operations 610 can trigger the methods of the present disclosure. For example, implementing physical components (including, for example, hardware, such as sensors) deployed in the field operations 610 can generate plans and signals that can be provided as input or feedback (or both) to the methods of the present disclosure.

Examples of computational operations 612 include one or more computer systems 620 that include one or more processors and computer-readable media (e.g., non-transitory computer-readable media) operatively coupled to the one or more processors to execute computer operations to perform the methods of the present disclosure. The computational operations 612 can be implemented using one or more databases 618, which store data received from the field operations 610 and/or generated internally within the computational operations 612 (e.g., by implementing the methods of the present disclosure) or both. For example, the one or more computer systems 620 process inputs from the field operations 610 to assess conditions in the physical world, the outputs of which are stored in the databases 618. For example, seismic sensors of the field operations 610 can be used to perform a seismic survey to map subterranean features, such as facies and faults. In performing a seismic survey, seismic sources (e.g., seismic vibrators or explosions) generate seismic waves that propagate in the earth and seismic receivers (e.g., geophones) measure reflections generated as the seismic waves interact with boundaries between layers of a subsurface formation. The source and received signals are provided to the computational operations 612 where they are stored in the databases 618 and analyzed by the one or more computer systems 620.

In some implementations, one or more outputs 622 generated by the one or more computer systems 620 can be provided as feedback/input to the field operations 610 (either as direct input or stored in the databases 618). The field operations 610 can use the feedback/input to control physical components used to perform the field operations 610 in the real world.

For example, the computational operations 612 can process the seismic data to generate 3D maps of the subsurface formation. The computational operations 612 can use these 3D maps to provide plans for locating and drilling exploratory wells. In some operations, the exploratory wells are drilled using logging-while-drilling (LWD) techniques which incorporate logging tools into the drill string. LWD techniques can enable the computational operations 612 to process new information about the formation and control the drilling to adjust to the observed conditions in real-time.

The one or more computer systems 620 can update the 3D maps of the subsurface formation as information from one exploration well is received and the computational operations 612 can adjust the location of the next exploration well based on the updated 3D maps. Similarly, the data received from production operations can be used by the computational operations 612 to control components of the production operations. For example, production well and pipeline data can be analyzed to predict slugging in pipelines leading to a refinery and the computational operations 612 can control machine operated valves upstream of the refinery to reduce the likelihood of plant disruptions that run the risk of taking the plant offline.

In some implementations of the computational operations 612, customized user interfaces can present intermediate or final results of the above-described processes to a user. Information can be presented in one or more textual, tabular, or graphical formats, such as through a dashboard. The information can be presented at one or more on-site locations (such as at an oil well or other facility), on the Internet (such as on a webpage), on a mobile application (or app), or at a central processing facility.

The presented information can include feedback, such as changes in parameters or processing inputs, that the user can select to improve a production environment, such as in the exploration, production, and/or testing of petrochemical processes or facilities. For example, the feedback can include parameters that, when selected by the user, can cause a change to, or an improvement in, drilling parameters (including drill bit speed and direction) or overall production of a gas or oil well. The feedback, when implemented by the user, can improve the speed and accuracy of calculations, streamline processes, improve models, and solve problems related to efficiency, performance, safety, reliability, costs, downtime, and the need for human interaction.

In some implementations, the feedback can be implemented in real-time, such as to provide an immediate or near-immediate change in operations or in a model. The term real-time (or similar terms as understood by one of ordinary skill in the art) means that an action and a response are temporally proximate such that an individual perceives the action and the response occurring substantially simultaneously. For example, the time difference for a response to display (or for an initiation of a display) of data following the individual's action to access the data can be less than 1 millisecond (ms), less than 1 second(s), or less than 5 s. While the requested data need not be displayed (or initiated for display) instantaneously, it is displayed (or initiated for display) without any intentional delay, taking into account processing limitations of a described computing system and time required to, for example, gather, accurately measure, analyze, process, store, or transmit the data.

Events can include readings or measurements captured by downhole equipment such as sensors, pumps, bottom hole assemblies, or other equipment. The readings or measurements can be analyzed at the surface, such as by using applications that can include modeling applications and machine learning. The analysis can be used to generate changes to settings of downhole equipment, such as drilling equipment. In some implementations, values of parameters or other variables that are determined can be used automatically (such as through using rules) to implement changes in oil or gas well exploration, production/drilling, or testing. For example, outputs of the present disclosure can be used as inputs to other equipment and/or systems at a facility. This can be especially useful for systems or various pieces of equipment that are located several meters or several miles apart, or are located in different countries or other jurisdictions.

Implementations of the subject matter and the functional operations described in this specification can be implemented in digital electronic circuitry, in tangibly embodied computer software or firmware, in computer hardware, including the structures disclosed in this specification and their structural equivalents, or in combinations of one or more of them. Software implementations of the described subject matter can be implemented as one or more computer programs, that is, one or more modules of computer program instructions encoded on a tangible, non-transitory, computer-readable medium for execution by, or to control the operation of, a computer or computer-implemented system. Alternatively, or additionally, the program instructions can be encoded in/on an artificially generated propagated signal, for example, a machine-generated electrical, optical, or electromagnetic signal that is generated to encode information for transmission to a receiver apparatus for execution by a computer or computer-implemented system. The computer-storage medium can be a machine-readable storage device, a machine-readable storage substrate, a random or serial access memory device, or a combination of computer-storage mediums. Configuring one or more computers means that the one or more computers have installed hardware, firmware, or software (or combinations of hardware, firmware, and software) so that when the software is executed by the one or more computers, particular computing operations are performed. The computer storage medium is not, however, a propagated signal.

The term “real-time,” “real time,” “realtime,” “real (fast) time (RFT),” “near(ly) real-time (NRT),” “quasi real-time,” or similar terms (as understood by one of ordinary skill in the art), means that an action and a response are temporally proximate such that an individual perceives the action and the response occurring substantially simultaneously. For example, the time difference for a response to display (or for an initiation of a display) of data following the individual's action to access the data can be less than 1 millisecond (ms), less than 1 second(s), or less than 5 s. While the requested data need not be displayed (or initiated for display) instantaneously, it is displayed (or initiated for display) without any intentional delay, taking into account processing limitations of a described computing system and time required to, for example, gather, accurately measure, analyze, process, store, or transmit the data.

The terms “data processing apparatus,” “computer,” “computing device,” or “electronic computer device” (or an equivalent term as understood by one of ordinary skill in the art) refer to data processing hardware and encompass all kinds of apparatuses, devices, and machines for processing data, including by way of example, a programmable processor, a computer, or multiple processors or computers. The computer can also be, or further include special-purpose logic circuitry, for example, a central processing unit (CPU), a field-programmable gate array (FPGA), or an application-specific integrated circuit (ASIC). In some implementations, the computer or computer-implemented system or special-purpose logic circuitry (or a combination of the computer or computer-implemented system and special-purpose logic circuitry) can be hardware-or software-based (or a combination of both hardware-and software-based). The computer can optionally include code that creates an execution environment for computer programs, for example, code that constitutes processor firmware, a protocol stack, a database management system, an operating system, or a combination of execution environments. The present disclosure contemplates the use of a computer or computer-implemented system with an operating system, for example LINUX, UNIX, WINDOWS, MAC OS, ANDROID, or IOS, or a combination of operating systems.

A computer program, which can also be referred to or described as a program, software, a software application, a unit, a module, a software module, a script, code, or other component can be written in any form of programming language, including compiled or interpreted languages, or declarative or procedural languages, and it can be deployed in any form, including, for example, as a stand-alone program, module, component, or subroutine, for use in a computing environment. A computer program can, but need not, correspond to a file in a file system. A program can be stored in a portion of a file that holds other programs or data, for example, one or more scripts stored in a markup language document, in a single file dedicated to the program in question, or in multiple coordinated files, for example, files that store one or more modules, sub-programs, or portions of code. A computer program can be deployed to be executed on one computer or on multiple computers that are located at one site or distributed across multiple sites and interconnected by a communication network.

While portions of the programs illustrated in the various figures can be illustrated as individual components, such as units or modules, that implement described features and functionality using various objects, methods, or other processes, the programs can instead include a number of sub-units, sub-modules, third-party services, components, libraries, and other components, as appropriate. Conversely, the features and functionality of various components can be combined into single components, as appropriate. Thresholds used to make computational determinations can be statically, dynamically, or both statically and dynamically determined.

Described methods, processes, or logic flows represent one or more examples of functionality consistent with the present disclosure and are not intended to limit the disclosure to the described or illustrated implementations, but to be accorded the widest scope consistent with described principles and features. The described methods, processes, or logic flows can be performed by one or more programmable computers executing one or more computer programs to perform functions by operating on input data and generating output data. The methods, processes, or logic flows can also be performed by, and computers can also be implemented as, special-purpose logic circuitry, for example, a CPU, an FPGA, or an ASIC.

Computers for the execution of a computer program can be based on general or special-purpose microprocessors, both, or another type of CPU. Generally, a CPU will receive instructions and data from and write to a memory. The essential elements of a computer are a CPU, for performing or executing instructions, and one or more memory devices for storing instructions and data. Generally, a computer will also include, or be operatively coupled to, receive data from or transfer data to, or both, one or more mass storage devices for storing data, for example, magnetic, magneto-optical disks, or optical disks. However, a computer need not have such devices. Moreover, a computer can be embedded in another device, for example, a mobile telephone, a personal digital assistant (PDA), a mobile audio or video player, a game console, a global positioning system (GPS) receiver, or a portable memory storage device, for example, a universal serial bus (USB) flash drive, to name just a few.

Non-transitory computer-readable media for storing computer program instructions and data can include all forms of permanent/non-permanent or volatile/non-volatile memory, media and memory devices, including by way of example semiconductor memory devices, for example, random access memory (RAM), read-only memory (ROM), phase change memory (PRAM), static random access memory (SRAM), dynamic random access memory (DRAM), erasable programmable read-only memory (EPROM), electrically erasable programmable read-only memory (EEPROM), and flash memory devices; magnetic devices, for example, tape, cartridges, cassettes, internal/removable disks; magneto-optical disks; and optical memory devices, for example, digital versatile/video disc (DVD), compact disc (CD)-ROM, DVD+/−R, DVD-RAM, DVD-ROM, high-definition/density (HD)-DVD, and BLU-RAY/BLU-RAY DISC (BD), and other optical memory technologies. The memory can store various objects or data, including caches, classes, frameworks, applications, modules, backup data, jobs, web pages, web page templates, data structures, database tables, repositories storing dynamic information, or other appropriate information including any parameters, variables, algorithms, instructions, rules, constraints, or references. Additionally, the memory can include other appropriate data, such as logs, policies, security or access data, or reporting files. The processor and the memory can be supplemented by, or incorporated in, special-purpose logic circuitry.

To provide for interaction with a user, implementations of the subject matter described in this specification can be implemented on a computer having a display device, for example, a cathode ray tube (CRT), liquid crystal display (LCD), light emitting diode (LED), or plasma monitor, for displaying information to the user and a keyboard and a pointing device, for example, a mouse, trackball, or trackpad by which the user can provide input to the computer. Input can also be provided to the computer using a touchscreen, such as a tablet computer surface with pressure sensitivity or a multi-touch screen using capacitive or electric sensing. Other types of devices can be used to interact with the user. For example, feedback provided to the user can be any form of sensory feedback (such as, visual, auditory, tactile, or a combination of feedback types). Input from the user can be received in any form, including acoustic, speech, or tactile input. In addition, a computer can interact with the user by sending documents to and receiving documents from a client computing device that is used by the user (for example, by sending web pages to a web browser on a user's mobile computing device in response to requests received from the web browser).

The term “graphical user interface (GUI) can be used in the singular or the plural to describe one or more graphical user interfaces and each of the displays of a particular graphical user interface. Therefore, a GUI can represent any graphical user interface, including but not limited to, a web browser, a touch screen, or a command line interface (CLI) that processes information and efficiently presents the information results to the user. In general, a GUI can include a number of user interface (UI) elements, some or all associated with a web browser, such as interactive fields, pull-down lists, and buttons. These and other UI elements can be related to or represent the functions of the web browser.

Implementations of the subject matter described in this specification can be implemented in a computing system that includes a back-end component, for example, as a data server, or that includes a middleware component, for example, an application server, or that includes a front-end component, for example, a client computer having a graphical user interface or a Web browser through which a user can interact with an implementation of the subject matter described in this specification, or any combination of one or more such back-end, middleware, or front-end components. The components of the system can be interconnected by any form or medium of wireline or wireless digital data communication (or a combination of data communication), for example, a communication network. Examples of communication networks include a local area network (LAN), a radio access network (RAN), a metropolitan area network (MAN), a wide area network (WAN), Worldwide Interoperability for Microwave Access (WIMAX), a wireless local area network (WLAN) using, for example, 802.11x or other protocols, all or a portion of the Internet, another communication network, or a combination of communication networks. The communication network can communicate with, for example, Internet Protocol (IP) packets, frame relay frames, Asynchronous Transfer Mode (ATM) cells, voice, video, data, or other information between network nodes.

The computing system can include clients and servers. A client and server are generally remote from each other and typically interact through a communication network. The relationship of client and server arises by virtue of computer programs running on the respective computers and having a client-server relationship to each other.

While this specification contains many specific implementation details, these should not be construed as limitations on the scope of any inventive concept or on the scope of what can be claimed, but rather as descriptions of features that can be specific to particular implementations of particular inventive concepts. Certain features that are described in this specification in the context of separate implementations can also be implemented, in combination, in a single implementation. Conversely, various features that are described in the context of a single implementation can also be implemented in multiple implementations, separately, or in any sub-combination. Moreover, although previously described features can be described as acting in certain combinations and even initially claimed as such, one or more features from a claimed combination can, in some cases, be excised from the combination, and the claimed combination can be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations can be considered optional), to achieve desirable results. In certain circumstances, multitasking or parallel processing (or a combination of multitasking and parallel processing) can be advantageous and performed as deemed appropriate.

The separation or integration of various system modules and components in the previously described implementations should not be understood as requiring such separation or integration in all implementations, and it should be understood that the described program components and systems can generally be integrated together in a single software product or packaged into multiple software products.

Accordingly, the previously described example implementations do not define or constrain the present disclosure. Other changes, substitutions, and alterations are also possible without departing from the scope of the present disclosure.

Furthermore, any claimed implementation is considered to be applicable to at least a computer-implemented method; a non-transitory, computer-readable medium storing computer-readable instructions to perform the computer-implemented method; and a computer system comprising a computer memory interoperably coupled with a hardware processor configured to perform the computer-implemented method or the instructions stored on the non-transitory, computer-readable medium.

What is claimed is:

1. A computer implemented method, comprising:
obtaining input data associated with changes of properties of a geological model of a reservoir due to fracking events;
generating a simulation event file, wherein the simulation event file includes instructions to provide portions of the input data to guide an execution of a numerical simulation model, and wherein the instructions are generated for each of the fracking events;
providing the simulation event file as input during the execution of the numerical simulation model to calibrate, based on the instructions of the simulation event file, the numerical simulation model with the geological model of the reservoir; and
generating a calibrated numerical simulation model based on processing the input data associated with the changes of the properties of the geological model of the reservoir during the execution of the numerical simulation model.

2. The computer implemented method of claim 1, comprising:
providing the calibrated numerical simulation model for use in reservoir development.

3. The computer implemented method of claim 1, wherein generating the simulation event file comprises:
chronologically sorting the fracking events based on time stamps associated with each event of the fracking events,
wherein the instructions correspond to the fracking events, wherein the instructions include the input data for each of the fracking events generated based on the input data, and wherein the instructions are ordered in the simulation event file according to the chronologically sorted fracking events.

4. The computer implemented method of claim 1, wherein the input data is for a set of the properties of the geological model, the set of the properties including permeability and porosity.

5. The computer implemented method of claim 1, wherein the input data is historical data associated with observed fracking events for the reservoir.

6. The computer implemented method of claim 1, wherein the input data is prediction data including prediction values for properties associated with the properties of the reservoir, wherein the prediction values are associated with predicted future fracking events.

7. The computer implemented method of claim 1, wherein each instruction from instructions part of the simulation event file comprises data for one or more of: reservoir properties, fracture properties, and well constraints, and wherein the geological model of the reservoir comprises static reservoir properties and dynamic reservoir properties.

8. The computer implemented method of claim 1, wherein during the execution of the numerical simulation model, portions of data from the simulation event file are provided, each portion corresponding to a fracking event, and wherein during the processing of a first portion of the input data that is provided for use during a simulation, a timestep size is applied, wherein the timestep size is determined according to a size rule for updating of the properties of the reservoir at the numerical simulation model.

9. The computer implemented method of claim 8, wherein the size rule defines at least one threshold value to be used as the timestep size for each processing of a portion of the input data during the simulation to maintain smooth convergence.

10. A non-transitory computer-readable medium coupled to one or more processors and having instructions stored thereon which, when executed by the one or more processors, cause the one or more processors to perform operations, the operations comprising:
obtaining input data associated with changes of properties of a geological model of a reservoir due to fracking events;
generating a simulation event file, wherein the simulation event file includes instructions to provide portions of the input data to guide an execution of a numerical simulation model, and wherein the instructions are generated for each of the fracking events;
providing the simulation event file as input during the execution of the numerical simulation model to calibrate, based on the instructions of the simulation event file, the numerical simulation model with the geological model of the reservoir; and
generating a calibrated numerical simulation model based on processing the input data associated with the changes of the properties of the geological model of the reservoir during the execution of the numerical simulation model.

11. The non-transitory computer-readable medium of claim 10, comprising further instructions, which when executed by the one or more processors, cause the one or more processors to perform operations comprising:
providing the calibrated numerical simulation model for use in reservoir development.

12. The non-transitory computer-readable medium of claim 10, wherein generating the simulation event file comprises:
chronologically sorting the fracking events based on time stamps associated with each event of the fracking events,
wherein the instructions correspond to the fracking events, wherein the instructions include the input data for each of the fracking events generated based on the input data, and wherein the instructions are ordered in the simulation event file according to the chronologically sorted fracking events.

13. The non-transitory computer-readable medium of claim 10, wherein the input data is for a set of the properties of the geological model, the set of the properties including permeability and porosity.

14. The non-transitory computer-readable medium of claim 10, wherein the input data is historical data associated with observed fracking events for the reservoir.

15. The non-transitory computer-readable medium of claim 10, wherein the input data is prediction data including prediction values for properties associated with the properties of the reservoir, wherein the prediction values are associated with predicted future fracking events.

16. The non-transitory computer-readable medium of claim 10, wherein each instruction from instructions part of the simulation event file comprises data for one or more of: reservoir properties, fracture properties, and well constraints, and wherein the geological model of the reservoir comprises static reservoir properties and dynamic reservoir properties.

17. A system comprising:
a computing device; and
a computer-readable storage device coupled to the computing device and having instructions stored thereon which, when executed by the computing device, cause the computing device to perform operations, the operations comprising:
obtaining input data associated with changes of properties of a geological model of a reservoir due to fracking events;
generating a simulation event file, wherein the simulation event file includes instructions to provide portions of the input data to guide an execution of a numerical simulation model, and wherein the instructions are generated for each of the fracking events;
providing the simulation event file as input during the execution of the numerical simulation model to calibrate, based on the instructions of the simulation event file, the numerical simulation model with the geological model of the reservoir; and
generating a calibrated numerical simulation model based on processing the input data associated with the changes of the properties of the geological model of the reservoir during the execution of the numerical simulation model.

18. The system of claim 17, wherein the computer-readable storage device comprises further instructions, which when executed by the computing device, cause the computing device to perform operations comprising:
providing the calibrated numerical simulation model for use in reservoir development.

19. The system of claim 17, wherein generating the simulation event file comprises:
chronologically sorting the fracking events based on time stamps associated with each event of the fracking events,
wherein the instructions correspond to the fracking events, wherein the instructions include the input data for each of the fracking events generated based on the input data, and wherein the instructions are ordered in the simulation event file according to the chronologically sorted fracking events.

20. The system of claim 17, wherein the input data is for a set of the properties of the geological model, the set of the properties including permeability and porosity.
